(19) United States
(12) Patent Application Publication
(10) Pub. No.: US 2015/0373836 A1
(43) Pub. Date: Dec. 24, 2015

(54) SEMICONDUCTOR DEVICE

(71) Applicant: KABUSHIKI KAISHA TOYOTA JIDOSHOKKI, Kariya-shi (JP)

(72) Inventor: Munehiko MASUTANI, Aichi-ken (JP)

(73) Assignee: KABUSHIKI KAISHA TOYOTA JIDOSHOKKI, Kariya-shi (JP)

(21) Appl. No.: 14/743,169

(22) Filed: Jun. 18, 2015

(30) Foreign Application Priority Data
Jun. 20, 2014 (JP) 2014-127399

(51) Int. Cl. H05K 1/02; H05K 1/18

(52) U.S. Cl. CPC H05K 1/0216; H05K 1/181

(57) ABSTRACT

There is provided a semiconductor device including a mounting substrate, a semiconductor element mounted on the mounting substrate, a laminated body laminated by a positive terminal plate and a negative terminal plate with a first insulating layer interposed therebetween, and a shield plate bonded to the laminated body with a second insulating layer interposed therebetween on the side of the laminated body that is opposite from the mounting substrate. The positive terminal plate and the negative terminal plate are electrically connected to the semiconductor element.

### BACKGROUND OF THE INVENTION

The present invention relates to a semiconductor device having a laminated body in which a positive terminal plate and a negative terminal plate are laminated through an insulating layer.

In general, the inductance of a semiconductor device is desired to be reduced for decreasing the heat generated by operation of the semiconductor device. Japanese Patent Application Publication No. 2010-35347 discloses a power converter device which has a laminated wiring substrate (laminated body) that is formed by laminating a positive conductor plate (positive terminal plate) and a negative conductor plate (negative terminal plate) with an insulating sheet (insulating layer) interposed therebetween, so that currents flowing in the positive conductor plate and the negative conductor plate flow in opposite directions. Therefore, the magnetic flux generated by the current flowing in the positive conductor plate and the magnetic flux generated by the current flowing in the negative conductor plate are canceled by mutual induction, with the result that the inductance between the positive and the negative conductor plates is decreased.

A semiconductor device usually includes a mounting substrate mounting thereon semiconductor elements and may further include a circuit substrate that is different from the mounting substrate and located facing the semiconductor elements of the mounting substrate. In this case, there is a fear that the electromagnetic noise generated by the semiconductor elements may cause malfunction of the circuit substrate. As a means to solve the problem, a shield plate may be provided between the mounting substrate and the circuit substrate to shield the electromagnetic noise from the semiconductor elements. Thus, the propagation of the electromagnetic noise from the semiconductor elements to the circuit substrate is restricted.

However, such a shield plate needs a support member that supports the shield plate between the mounting substrate and the circuit substrate. The provision of such a support member makes the semiconductor device larger in size. Furthermore, the shield plate needs a process for assembling the shield plate to the support member, with the result that the time for assembling the semiconductor device is increased, resulting in reduced productivity.

The present invention, which has been made in view of the above problems, is directed to providing a semiconductor device that can be made small in size and reduce the assembling time.

### SUMMARY OF THE INVENTION

There is provided a semiconductor device including a mounting substrate, a semiconductor element mounted on the mounting substrate, a laminated body laminated by a positive terminal plate and a negative terminal plate with a first insulating layer interposed therebetween, and a shield plate bonded to the laminated body with a second insulating layer interposed therebetween on the side of the laminated body that is opposite from the mounting substrate. The positive terminal plate and the negative terminal plate are electrically connected to the semiconductor element.

Other aspects and advantages of the invention will become apparent from the following description, taken in conjunction with the accompanying drawings, illustrating by way of example the principles of the invention.

### BRIEF DESCRIPTION OF THE DRAWINGS

The invention together with objects and advantages thereof, may best be understood by reference to the following description of the presently preferred embodiments together with the accompanying drawings in which:

FIG. 1 is an exploded perspective view of a semiconductor device according to an embodiment of the present invention;

FIG. 2 is an exploded perspective view showing a laminated body and insulating layers of the semiconductor device of FIG. 1; and

FIG. 3 is a perspective view of the semiconductor device, showing a state in which the laminated body having a shield plate bonded thereto is mounted on a mounting substrate in the semiconductor device of FIG. 1.

### DETAILED DESCRIPTION OF THE EMBODIMENTS

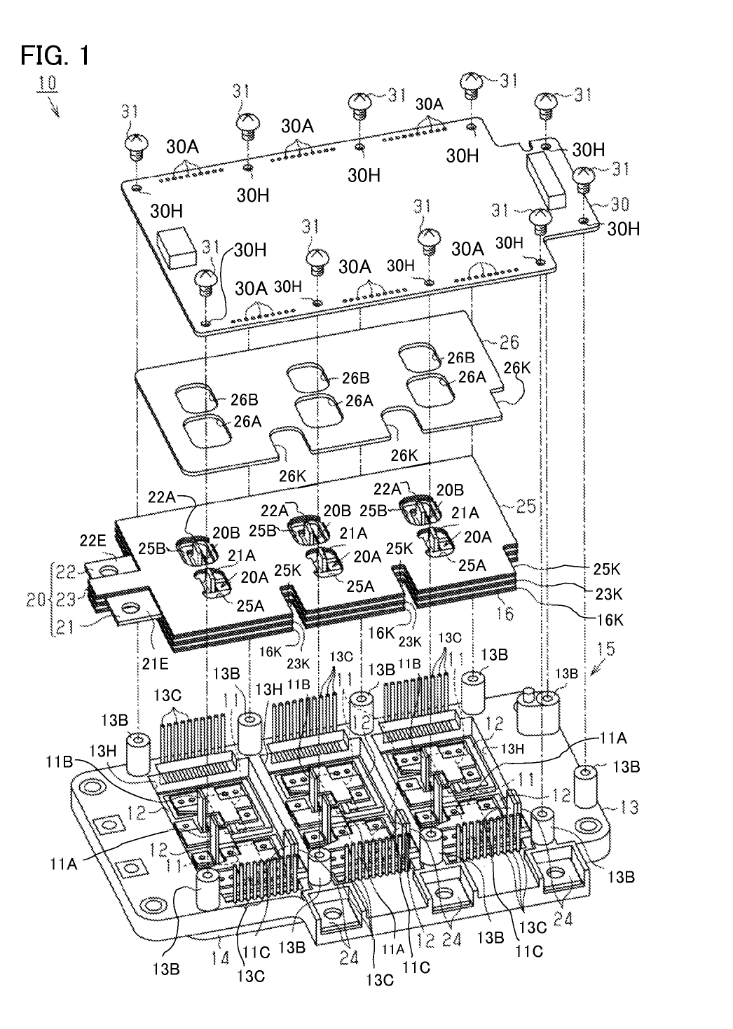

The following will describe a semiconductor device according to an embodiment of the present invention with reference to FIGS. 1 through 3. As shown in FIG. 1, the semiconductor device that is designated generally by numeral 10 includes a plurality of mounting substrates 12 (six mounting substrates in the embodiment) on which semiconductor elements 11 are mounted, respectively and a housing 13 having a generally rectangular frame shape. Though not shown in the drawing, the mounting substrate 12 has thereon two IGBTs and two diodes as the semiconductor elements 11. The mounting substrate 12 is set on a heat sink 14 with an insulating layer not shown interposed therebetween. The housing 13 is set on the heat sink 14. The semiconductor elements 11, the mounting substrates 12, the housing 13, and the heat sink 14 cooperate to form a power module 15.

The housing 13 is made of a resin and has therein a plurality of housing holes 13H (three housing holes in the embodiment) that are of a rectangular shape in a plan view. Each housing hole 13H has therein two mounting substrate 12. A plurality of boss portions 13B (ten boss portions in the embodiment) is disposed surrounding the housing holes 13H and formed extending from the housing 13 on the side thereof that is the opposite from the heat sink 14. A plurality of groups of signal terminals 13C is disposed in the longitudinal direction of the housing 13 and the group of the signal terminals 13C is disposed between any two adjacent boss portions 13B and extends from the housing 13. The signal terminals 13C are electrically connected to patterns on the mounting substrates 12, respectively. A laminated body 20 is mounted covering part over the semiconductor elements 11.

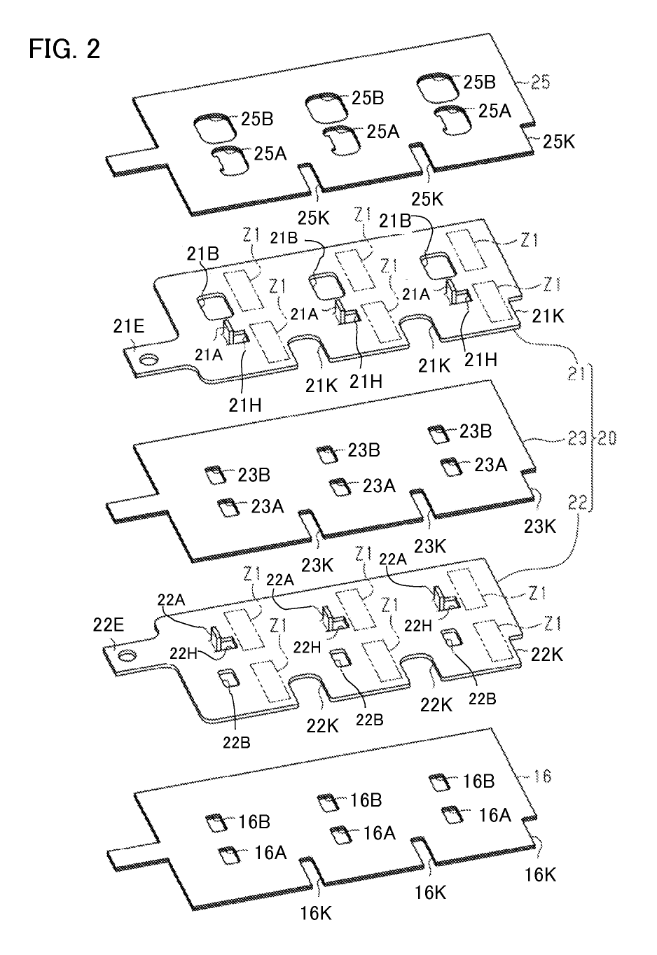

As shown in FIG. 2, the laminated body 20 includes a positive terminal plate 21 and a negative terminal plate 22 that are electrically connected to the semiconductor elements 11 are laminated through a first insulating layer 23 that is formed of two sheets of insulating paper. The positive terminal plate 21 and the negative terminal plate 22 are of a generally rectangular plate shape including regions Z1 (region surrounded by phantom lines) where parts of the positive terminal plate 21 and the negative terminal plate 22 lie over the semiconductor elements 11 of the mounting substrate 12, respectively

The negative terminal plate 22 is located on the side of the first insulating layer 23 that is adjacent to the mounting substrate 12 in the laminating direction of the laminated body 20. It is noted that the laminating direction of the laminated body 20 means the direction in which the positive terminal plate 21, the negative terminal plate 22, and the first insulating layer 23 are laminated together.

The positive terminal plate 21 includes a positive power source terminal 21 E connected to a positive terminal of power source (not shown). The positive power source terminal 21E extends from one short side edge of the positive terminal plate 21 of a rectangular shape along the surface of the positive terminal plate 21. The negative terminal plate 22 includes a negative power source terminal 22E connected to a negative terminal of power source (not shown). The negative power source terminal 22E extends from one short side edge of the negative terminal plate 22 of a rectangular shape along the surface of the negative terminal plate 22. The positive power source terminal 21E and the negative power source terminal 22E are disposed spaced away from each other in the width direction of the positive and negative terminal plates 21 and 22 so as not to overlap each other.

As shown in FIG. 1, the two mounting substrates 12 accommodated in the housing hole 13H are connected in series. The semiconductor element 11 accommodated in one of any two adjacent housing holes 13H that are disposed in side-by-side relation to each other in the width direction of the semiconductor device 10 has a positive electrode connecting plate 11A that is electrically connected to the positive terminal plate 21. The positive electrode connecting plate 11A is of a thin plate shape and extends in a direction away from the mounting substrate 12 in the laminating direction of the laminated body 20. Furthermore, the semiconductor element 11 accommodated in the other of the above two housing holes 13H has a negative electrode connecting plate 11B that is electrically connected to the negative terminal plate 22. The negative electrode connecting plate 11B is of a thin plate shape and extends in a direction away from the mounting substrate 12 in the laminating direction of the laminated body 20.

The semiconductor device 10 has a connecting terminal 11C that has a thin plate shape and electrically connects the mounting substrates 12 accommodated in the above two adjacent housing holes 13H. One end of the connecting terminal 11C is electrically connected to the two mounting substrates 12 and the other end of the connecting terminal 11C extends in a direction away from the mounting substrate 12 in the laminating direction of the laminated body 20. The connecting terminal 11C is connected to a load (not shown) such as a motor through a bus bar 24. A part of the bus bar 24 is embedded in the housing 13. One end of the bus bar 24 extends in a direction away from the mounting substrate 12 in the laminated direction of the laminated body 20 and the other end is connected to the load.

As shown in FIG. 2, the negative terminal plate 22 has three negative terminal portions 22A that integrally extend in the direction that is away from the mounting substrate 12 in the laminating direction of the laminated body 20. The negative terminal portions 22A are disposed at a predetermined interval in the longitudinal direction of the negative terminal plate 22. The negative terminal plate 22 has openings 22H through which the negative electrode connecting plates 11B can be inserted. The opening 22H is formed by forming the negative terminal portion 22A by bending. The negative terminal plate 22 further has openings 22B through which the positive electrode connecting plates 11A can be inserted and has recesses 22K through which one ends of the connecting terminals 11C and one ends of the bus bars 24 can be inserted.

The positive terminal plate 21 has three positive terminal portions 21A that integrally extend in the direction that is away from the mounting substrate 12 in the laminating direction of the laminated body 20. The positive terminal portions 21A are disposed at a predetermined interval in the longitudinal direction of the positive terminal plate 21. The positive terminal portions 21A are spaced away from the negative terminal portion 22A in the width direction of the positive terminal plate 21 and the negative terminal plate 22. The positive terminal plate 21 has openings 21H through which the positive electrode connecting plates 11A can be inserted. The opening 21H is formed by forming the positive terminal portion 21A by bending. The positive terminal plate 21 further has openings 21B through which the negative electrode connecting plates 11B and the negative terminal portions 22A can be inserted and has recesses 21K through which one ends of the connecting terminals 11C and one ends of bus bars 24 can be inserted.

The first insulating layer 23 has therethrough openings 23A through which the positive electrode connecting plate 11A are inserted. Furthermore, the first insulating layer 23 has therethrough openings 23B through which the negative electrode connecting plates 11B and the negative terminal portions 22A are inserted. The first insulating layer 23 also has recesses 23K through which one ends of the connecting terminal 11C and one ends of the bus bars 24 are inserted.

The laminated body 20 has a third insulating layer 16 that is formed of two sheets of insulating paper and bonded to the laminated body 20 on the side thereof that is adjacent to the mounting substrate 12. The third insulating layer 16 has therethrough an opening 16A through which the positive electrode connecting plates 11A are inserted and openings 16B through which the positive electrode connecting plates 11A are inserted. The third insulating layer 16 also has therein recesses 16K through which one ends of the connecting terminals 11C and one ends of the bus bars 24 are inserted.

The laminated body 20 further has a second insulating layer 25 that is formed of two sheets of insulating paper and bonded to the laminated body 20 on the side thereof that is opposite from the mounting substrate 12. The second insulating layer 25 has therethrough openings 25A through which the positive electrode connecting plate 11A and the positive terminal portion 21A are inserted and openings 25B through which the negative electrode connecting plates 11B and the negative terminal portions 22A are inserted. The second insulating layer 25 also has therein recesses 25K through which one ends of the connecting terminals 11C and one ends of the bus bars 24 are inserted.

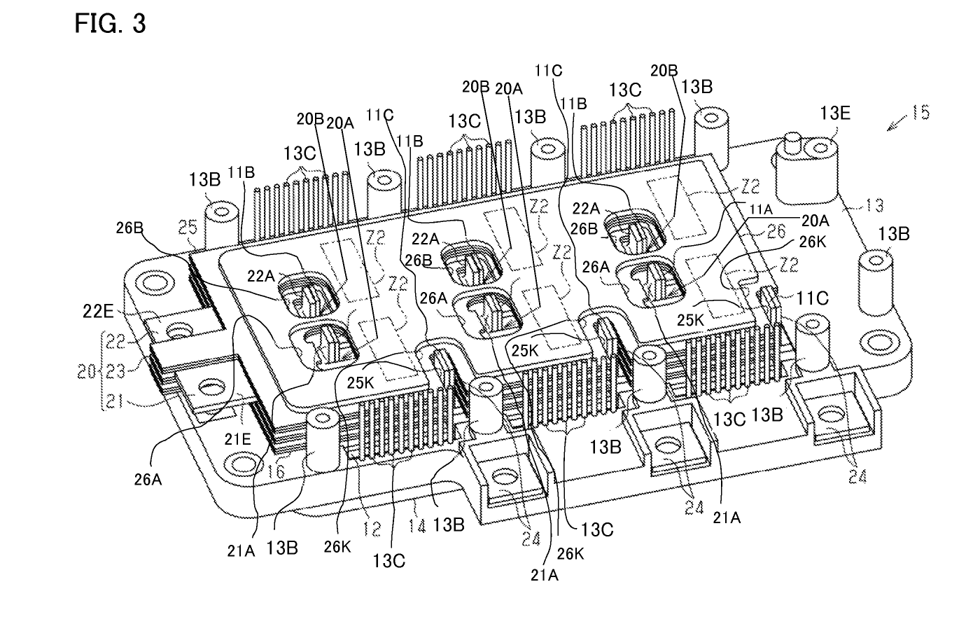

As shown in FIG. 3, the laminated body 20 includes a shield plate 26 that is bonded to the laminated body 20 with the second insulating layer 25 interposed therebetween on the side of the laminated body 20 that is opposite from the mounting substrate 12. The shield plate 26 is made of iron and grounded.

The shield plate 26 has therethrough void portions 26A through which the positive terminal portions 21A and the positive electrode connecting plates 11A are inserted. The void portions 26A may be formed by press punching an iron plate. The shield plate 26 also has therethrough void portions 26B through which the negative terminal portions 22A and the negative electrode connecting plates 11B are inserted. The void portions 26B may be formed by press punching. Furthermore, the shield plate 26 has therein recesses 26K through which one ends of the connecting terminals 11C and one ends of the bus bars 24 are inserted. The shield plate 26 includes regions Z2 (regions surrounded by phantom lines in FIG. 3) lying over the respective regions Z1. That is, the shield plate 26 has a generally rectangular planar shape and includes the region Z2 disposed over the semiconductor elements 11 on the mounting substrate 12.

The positive electrode connecting plates 11A extend to be inserted through the openings 16A of the third insulating layer 16, the openings 22B of the negative terminal plate 22, the openings 23A of the first insulating layer 23, the openings 21H of the positive terminal plate 21, the openings 25A of the second insulating layer 25, and the void portions 26A of the shield plate 26 and further extend in a direction away from the laminated body 20. Therefore, the laminated body 20 has openings 20A that are formed by the openings 22B of the negative terminal plate 22, the openings 23A of the first insulating layer 23 and the openings 21H of the positive terminal plate 21, and the positive electrode connecting plates 11A are inserted through the respective openings 20A.

The negative electrode connecting plates 11B extend to be inserted through the openings 16B of the third insulating layer 16, the openings 22H of the negative terminal plate 22, the openings 23B of the first insulating layer 23, the openings 21B of the positive terminal plate 21, the openings 25B of the second insulating layer 25, and the void portions 26B of the shield plate 26 and further extend in a direction away from the laminated body 20. Therefore, the laminated body 20 has openings 20B that are formed by the openings 22H of the negative terminal plate 22, the openings 23B of the first insulating layer 23, and the openings 21B of the positive terminal plate 21, and the negative electrode connecting plates 11B are inserted through the respective openings 20B.

The positive terminal portions 21A are inserted through the openings 25A of the second insulating layer 25 and the void portions 26A of the shield plate 26 and extend in a direction away from the laminated body 20. The negative terminal portions 22A are inserted through the openings 23B of the first insulating layer 23, the openings 21B of the positive terminal plate 21, the openings 25B of the second insulating layer 25, and the void portions 26B of the shield plate 26 and extend in a direction away from the laminated body 20.

The positive terminal portions 21A and the positive electrode connecting plates 11A are connected through metal junction on the side of the shield plate 26 that is opposite from the laminated body 20. The negative terminal portions 22A and the negative electrode connecting plate 11B are connected through metal junction on the side of the shield plate 26 that is opposite from the laminated body 20.

One ends of the connecting terminals 11C and one ends of the bus bars 24 are inserted through the recesses 16K of the third insulating layer 16, the recesses 22K of the negative terminal plate 22, the recesses 23K of the first insulating layer 23, the recesses 21 K of the positive terminal plate 21, the recesses 25K of the second insulating layer 25 and the recesses 26K of the shield plate 26, and extend in a direction away from the laminated body 20. One ends of the connecting terminals 11C and one ends of the bus bars 24 are connected through metal junction on the side of the shield plate 26 that is opposite from the laminated body 20.

As shown in FIG. 1, a circuit substrate 30 which is different from the mounting substrate 12 is located on the side of the laminated body 20 that is opposite from the mounting substrate 12. That is, the circuit substrate 30 is disposed above the shield plate 26 as viewed in FIG. 1. The circuit substrate 30 has therethrough a plurality of bolt holes 30H (ten holes in the embodiment) for receiving a bolt 31 and the circuit substrate 30 is assembled to the housing 13 by means of the bolts 31 that are inserted through the bolt holes 30H and screwed into threaded holes in the boss portions 13B. The circuit substrate 30 has therethrough a plurality of group of insert holes 30A (6 groups each having ten holes in the embodiment) through which the signal terminals 13C are inserted. The signal terminals 13C thus inserted in through the insert holes 30A are soldered to patterns of the circuit substrate 30, with the result that the circuit substrate 30 and the mounting substrate 12 are electrically connected. Accordingly, the circuit substrate 30 can drive the semiconductor elements 11.

The following will describe a process for manufacturing the above-described semiconductor device 10. Firstly, the mounting substrate 12 having thereon a plurality of the semiconductor elements 11 is placed on the heat sink 14 through an insulating layer that is not shown. Next, the positive electrode connecting plates 11A, the negative electrode connecting plates 11B, and the connecting terminal 11C are soldered to the semiconductor elements 11 and the housing 13 is bonded to the heat sink 14. The semiconductor elements 11 and the signal terminals 13C are then electrically connected by wire bonding. The semiconductor elements 11 are molded by resin and the laminated body 20 to which the third insulating layer 16, the second insulating layer 25, and the shield plate 26 are then bonded is mounted on the mounting substrate 12. Subsequently, the positive terminal portions 21A and the positive electrode connecting plates 11A are connected through metal junction, the negative terminal portions 22A and the negative electrode connecting plates 11B are connected through metal junction, and one ends of the connecting terminals 11C and one ends of the bus bars 24 are connected through metal junction. Then, the circuit substrate 30 and the housing 13 are assembled together by the bolts 31. Finally, the signal terminals 13C are soldered to patterns of the circuit substrate 30.

The following will describe the operation of the semiconductor device 10 of the above-described embodiment according to the present invention. The semiconductor device 10 in which the laminated body 20 is formed of laminating the positive terminal plate 21 and the negative terminal plate 22 with the first insulating layer 23 interposed therebetween so that the currents in the positive terminal plate 21 and the negative terminal plate 22 flow in opposite directions. Therefore, the magnetic flux generated by the current flowing in the positive terminal plate 21 and the magnetic flux generated by the current flowing in the negative terminal plate 22 are canceled by mutual induction, with the result that the inductance between the positive terminal plate 21 and the negative terminal plate 22 is decreased.

Furthermore, in the case that the semiconductor device 10 in which the circuit substrate 30 that is different from the mounting substrate 12 is disposed on the side of the shield plate 26 that is opposite from the mounting substrate 12, the propagation of electromagnetic noise from the semiconductor elements 11 to the circuit substrate 30 is restricted by the shield plate 26.

The above-described embodiment has the following advantageous effects. (1) The shield plate 26 is bonded to the laminated body 20 through the second insulating layer 25 on the side of the laminated body 20 that is opposite from the mounting substrate 12. As with the prior art, the laminated body 20 is configured so that the positive terminal plate 21 and the negative terminal plate 22 are laminated through the first insulating layer 23 with the first insulating layer 23 interposed therebetween to reduce the inductance of the positive terminal plate 21 and the negative terminal plate 22. Because the shield plate 26 is bonded to the laminated body 20, or the shield plate 26 is disposed between the mounting substrate 12 and the circuit substrate 30, no support member that supports the shield plate 26 between the mounting substrate 12 and the circuit substrate 30 is needed. Accordingly, manufacturing of the semiconductor device 10 needs no process for assembling the shield plate 26 with a support member and therefore, the laminated body 20 having the shield plate 26 bonded thereto may only be mounted on the mounting substrate 12. As a result, the assembling time for the semiconductor device 10 can be reduced and the semiconductor device 10 can be made smaller.

(2) The shield plate 26 and the semiconductor elements 11 lie one over the other in the laminating direction of the laminated body 20 and the circuit substrate 30 driving the semiconductor elements 11 and the shield plate 26 also lie one over the other in the same direction. According to such configuration, the propagation of the electromagnetic noise from the semiconductor elements 11 to the circuit substrate 30 can be restricted easily by the shield plate 26.

(3) The laminated body 20 has the openings 20A through which the positive electrode connecting plates 11A are inserted. The shield plate 26 has the void portions 26A through which the positive terminal portions 21A and the positive electrode connecting plates 11A are inserted. The positive terminal portions 21A and the positive electrode connecting plates 11A are connected through metal junction on the side of the shield plate 26 that is opposite from the laminated body 20. Because the positive terminal portions 21A and the positive electrode connecting plates 11A are located in the void portions 26A, the movement of the shield plate 26 relative to the laminated body 20 in the surface direction thereof may be restricted. As a result, the shield plate 26 is positioned accurately relative to the laminated body 20 and the electromagnetic noise generated by the semiconductor elements 11 is easily shielded.

(4) The laminated body 20 has the openings 20B through which the negative electrode connecting plates 11B are inserted. The shield plate 26 has the void portions 26B through which the negative terminal portions 22A and the negative electrode connecting plates 11B are inserted. The negative terminal portions 22A and the negative electrode connecting plates 11B are connected through metal junction on the side of the shield plate 26 that is opposite from the laminated body 20. Because the negative terminal portions 22A and the negative electrode connecting plate 11B are located in the void portions 26B, the movement of the shield plate 26 relative to the laminated body 20 in the surface direction thereof may be restricted, with the result that the shield plate 26 is positioned accurately relative to the laminated body 20 and the electromagnetic noise generated by the semiconductor elements 11 is easily shielded.

(5) The above-described semiconductor device 10, which dispenses with a support member to support the shield plate 26 between the mounting substrate 12 and the circuit substrate 30, can be made smaller and lighter. Furthermore, the configuration of the semiconductor device 10 using metal conjunction for connection of component parts can prevent the semiconductor device 10 from becoming larger in the wide direction thereof, as compared to the configuration using screws for the connection.

(6) The positive terminal portions 21A and the positive electrode connecting plates 11A are connected through metal junction on the side of the opposite side of the shield plate 26 that is opposite from the laminated body 20. The negative terminal portions 22A and the negative electrode connecting plates 11B are connected through metal junction on the side of the shield plate 26 that is opposite from the laminated body 20. According to such configuration, after the connection of the semiconductor element 11 by soldering to the positive electrode connecting plates 11A, the negative electrode connecting plates 11B and the connecting terminal 11C, the bonding of the mounting substrate 12 to the housing 13, and the molding of the semiconductor element 11 by resin, the positive terminal portion 21A and the positive electrode connecting plates 11A can be connected through metal junction and the negative terminal portions 22A and the negative electrode connecting plates 11B can be connected through metal junction.

The above-described embodiment may be modified variously as exemplified below. For example, the positive terminal portion 21A and the positive electrode connecting plate 11A may be electrically connected on the side of the laminated body 20 that is adjacent to the mounting substrate 12. In the case, the laminated body 20 may dispense with the openings 20A and the shield plate 26 with the void portions 26A, respectively.

For example, the negative terminal portion 22A and the negative electrode connecting plate 11B may be electrically connected on the side of the laminated body 20 that is adjacent to the mounting substrate 12. In the case, the laminated body 20 may dispense with the openings 20B and the shield plate 26 with the void portions 26B, respectively.

The first insulating layer 23 may be formed of, for example, a single sheet of insulating paper. The second insulating layer 25 may be formed of, for example, a single sheet of insulating paper.

The void portions 26A, 26B may be replaced by recesses such as 26K. The positive terminal plate 21 may be located adjacent or closer to the mounting substrate 12 in the laminating direction of the laminated body 20 than the negative terminal plate 22.

The semiconductor element 11 may be a MOSFET. The number of the semiconductor elements 11 is not limited to six. The shield plate 26 may be surface-finished by nickel plating and the like.

The shield plate 26 may be made of a ferrous alloy that shields electromagnetic noise. The shield plate 26 may include a region Z2 that lies over at least a part of the semiconductor element 11. In other words, the shield plate 26 may not lie over a part of the semiconductor element 11.

The positive terminal plate 21 and the negative terminal plate 22 may include a region Z1 that lies over at least a part of the semiconductor element 11. In other words, the positive terminal plate 21 and the negative terminal plate 22 may not lie over a part of the semiconductor element 11.

What is claimed is:

1. A semiconductor device comprising:
a mounting substrate;
a semiconductor element mounted on the mounting substrate;
a laminated body laminated by a positive terminal plate and a negative terminal plate with a first insulating layer interposed therebetween, the positive terminal plate and the negative terminal plate being electrically connected to the semiconductor element; and
a shield plate bonded to the laminated body with a second insulating layer interposed therebetween on the side of the laminated body that is opposite from the mounting substrate.

2. The semiconductor device according to claim 1, further comprising
a circuit substrate driving the semiconductor element, wherein the shield plate lies over at least a part of the semiconductor element in a laminated direction of the laminated body and wherein the circuit substrate lies over the shield plate.

3. The semiconductor device according to claim 1, further comprising
a positive electrode connecting plate that is electrically connected to the semiconductor element and extends in a direction away from the mounting substrate in the laminated direction of the laminated body, wherein the positive terminal plate has a positive terminal portion that integrally extends in a direction away from the mounting substrate in the laminated direction of the laminated body, wherein the laminated body has an opening through which the positive electrode connecting plate is inserted, wherein the shield plate has therein a void portion through which the positive terminal portion and the positive electrode connecting plate are inserted, and wherein the positive terminal portion and the positive electrode connecting plate are connected through metal junction on the side of the shield plate that is opposite from the laminated body.

4. The semiconductor device according to claim 1, further comprising
a negative electrode connecting plate that is electrically connected to the semiconductor element and extends in a direction away from the mounting substrate in the laminated direction of the laminated body, wherein the negative terminal plate having a negative terminal portion that integrally extends in a direction away from the mounting substrate in the laminated direction of the laminated body, wherein the laminated body has an opening through which the negative electrode connecting plate is inserted, wherein the shield plate has therein a void portion through which the negative terminal portion and the negative electrode connecting plate are inserted, and wherein the negative terminal portion and the negative electrode connecting plate are connected through metal junction on the side of the shield plate that is opposite from the laminated body.
